(19) United States
(12) Patent Application Publication
(10) Pub. No.: US 2009/0220865 A1
(43) Pub. Date: Sep. 3, 2009

(54) METHOD AND APPARATUS FOR SOURCE FIELD SHAPING IN A PLASMA ETCH REACTOR

(75) Inventor: ALAN HIROSHI OUYE, San Mateo, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 12/040,647

(22) Filed: Feb. 29, 2008

(51) Int. Cl. G03F 1/00; C23F 1/02

(52) U.S. Cl. 430/5; 156/345.49; 216/68

(57) ABSTRACT

A method and apparatus for improved plasma etching uniformity are provided herein. In one embodiment, a field-shaping magnet is disposed above the chamber processing volume and adjacent to field induction coils. The field-shaping magnet provides improved control of the etch rate at various locations along the surface of a substrate by providing adjustability in the radial profile of a plasma-producing electric field generated by the induction coils. In another embodiment, two field-shaping magnets are used to improve etching uniformity at the substrate surface.

### BACKGROUND

1. Field

Embodiments of the present invention generally relate to methods and apparatus for plasma etching and, in particular, to a method and apparatus which provide improved etch control in a plasma etch reactor.

2. Description of the Related Art

Semiconductor device geometries have dramatically decreased in size since such devices were first introduced several decades ago. Since then, integrated circuits have generally followed the two year/half-size rule (often called Moore's Law), which means that the number of devices on a chip doubles every two years. Today's fabrication plants are routinely producing devices having 0.15 μm and even 0.13 μm feature sizes, and tomorrow's plants soon will be producing devices having even smaller geometries.

The increasing circuit densities have placed additional demands on processes used to fabricate semiconductor devices. For example, as circuit densities increase, the widths of vias, contacts and other features, as well as the dielectric materials between them, decrease to sub-micron dimensions, whereas the thickness of the dielectric layers remains substantially constant, with the result that the aspect ratios for the features, i.e., their height divided by width, increases. Reliable formation of high aspect ratio features is important to the success of sub-micron technology and to the continued effort to increase circuit density and quality of individual substrates.

High aspect ratio features are conventionally formed by patterning a surface of a substrate to define the dimensions of the features and then etching the substrate to remove material and define the features. To form high aspect ratio features with a desired ratio of height to width, the dimensions of the features are required to be formed within certain parameters that are typically defined as the critical dimensions of the features. Consequently, reliable formation of high aspect ratio features with desired critical dimensions requires precise patterning and subsequent etching of the substrate.

Photolithography is a technique used to form precise patterns on the substrate surface, and then the patterned substrate surface is etched to form the desired device or features. Photolithography techniques use light patterns and resist materials deposited on a substrate surface to develop precise patterns on the substrate surface prior to the etching process. In conventional photolithographic processes, a resist is applied on the layer to be etched, and the features to be etched in the layer, such as contacts, vias, or interconnects, are defined by exposing the resist to a pattern of light through a photolithographic reticle having a photomask layer disposed thereon. The photomask layer corresponds to the desired configuration of features. A light source emitting ultraviolet (UV) light or low X-ray light, for example, may be used to expose the resist in order to alter the composition of the resist. Generally, the exposed resist material is removed by a chemical process to expose the underlying substrate material. The exposed underlying substrate material is then etched to form the features in the substrate surface while the retained resist material remains as a protective coating for the unexposed underlying substrate material.

Binary photolithographic reticles typically include a substrate made of an optically transparent silicon-based material, such as quartz (i.e., silicon dioxide, SiO₂), having an opaque light-shielding layer of metal, or photomask, typically chromium, disposed on the surface of the substrate. The light-shielding layer is patterned to correspond to the features to be transferred to the substrate. Binary photolithographic reticles are fabricated by first depositing a thin metal layer on a substrate comprising an optically transparent silicon-based material, and then depositing a resist layer on the thin metal layer. The resist is then patterned using conventional laser or electron beam patterning equipment to define the critical dimensions to be transferred to the metal layer. The metal layer is then etched to remove the metal material not protected by the patterned resist; thereby exposing the underlying optically transparent material and forming a patterned photomask layer. Photomask layers allow light to pass therethrough in a precise pattern onto the substrate surface. The terms “mask”, “photomask” or “reticle” will be used interchangeably to denote generally a substrate containing a precise pattern used for patterning other substrates.

Conventional etching processes, such as wet etching, tend to etch isotropically, which can result in an undercut phenomenon in the metal layer below the patterned resist. The undercut phenomenon can produce patterned features on the photomask that are not uniformly spaced and do not have desired straight, vertical sidewalls, thereby losing the critical dimensions of the features. Additionally, the isotropic etching of the features may over-etch the sidewalls of features in high aspect ratios, resulting in the loss of the critical dimensions of the features. Features formed without the desired critical dimensions in the metal layer can detrimentally affect light passing therethrough and result in less than desirable patterning by the photomask in subsequent photolithographic processes.

Plasma etch processing, known as dry etch processing or dry etching, provides a more anisotropic etch than wet etching processes. The dry etching process has been shown to produce less undercutting and to improve the retention of the critical dimensions of the photomask features with straighter sidewalls and flatter bottoms. However, dry etching may over-etch or imprecisely etch the sidewalls of the openings or pattern formed in the resist material used to define the critical dimensions of the metal layer, and imprecise etching may result from a lack of uniformity in the etching process across the photomask surface. Excess side removal of the resist material results in a loss of the critical dimensions of the patterned resist features, which may translate to a loss of critical dimensions of the features formed in the metal layer defined by the patterned resist layer. Further, imprecise etching may not sufficiently etch the features to provide the necessary critical dimensions. Failure to sufficiently etch the features to the critical dimensions is referred to as a “gain” of critical dimensions. The degree of loss or gain of the critical dimensions in the metal layer is referred to as “etching bias” or “CD bias”. The etching bias can be as large as 120 nm in photomask patterns used to form 0.14 μm features on substrate surfaces.

The loss or gain of critical dimensions of the pattern formed in the metal layer can detrimentally affect the light passing therethrough and produce numerous patterning defects and subsequent etching defects in the substrate patterned by the photolithographic reticle. The loss or gain of critical dimensions of the photomask can result in insufficient photolithographic performance for etching high aspect ratios of sub-micron features and, if the loss or gain of critical dimensions is severe enough, the failure of the photolithographic reticle or subsequently etched device.

With ever-decreasing device dimensions, the design and fabrication of photomasks for advanced technology becomes increasingly complex, and control of critical dimensions and etching uniformity becomes increasingly more important. Therefore, there is an ongoing need for improved plasma etching process control in photomask fabrication.

### SUMMARY

Embodiments of the present invention generally provide improved methods and apparatus for plasma etching of various substrates, such as photomasks, semiconductor wafers, or other types of substrates.

One embodiment provides an apparatus for plasma etching which includes a process chamber defining a processing volume, a substrate pedestal disposed in the process chamber and configured to support a substrate thereon, one or more induction coils disposed outside the chamber above the substrate pedestal, and a field-shaping magnet assembly having a field-shaping magnet which is disposed adjacent to an induction coil.

In another embodiment, a method is disclosed for improved etching using a processing chamber having a substrate pedestal and induction coils disposed outside the chamber and above the substrate pedestal, and at least one field-shaping magnet disposed adjacent to an induction coil and above said pedestal, the method includes generating an electric field within a substrate processing volume using the induction coils, and selectively modifying the electric field using at least one field-shaping magnet.

In another embodiment, an apparatus for improved plasma etching is provided. The apparatus generally includes a process chamber defining a processing volume, a substrate pedestal disposed in the process chamber and configured to support a substrate thereon, one or more induction coils disposed outside the chamber and above the substrate pedestal, and a field-shaping magnet assembly disposed within a boundary defined by one of the induction coils, the field-shaping magnet assembly including a field-shaping magnet having a magnet and mounting base and a support member having a support column and support base.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of an etch reactor.

FIG. 2 is a schematic view of an electric field produced by the induction coils shown in FIG. 1.

FIG. 3A is a schematic cross-sectional detail view of the chamber shown in FIG. 1.

FIG. 3B is a top view of the inductively coupled electric field shown in FIG. 3A.

FIG. 3C shows a plasma-produced ion flux for the chamber shown in FIG. 3A.

FIG. 4 is a schematic cross-sectional detail view of an etching chamber according to an embodiment of the invention that may be implemented in the etch reactor of FIG. 1.

FIG. 5 is a top view of the inductively coupled electric field shown in FIG. 4.

FIG. 6 shows a plasma-produced ion flux for the chamber shown in FIG. 4.

FIG. 7A is a top view of a field-shaping magnet shown in FIG. 4 according to one embodiment of the invention.

FIG. 7B is a top view of a field-shaping magnet shown in FIG. 4 according to a second embodiment of the invention.

FIG. 7C is a top view of the field-shaping magnet shown in FIG. 4 according to a third embodiment the present invention.

FIG. 8 is a schematic cross-sectional view of another embodiment of the chamber shown in FIG. 6 according to the present invention.

FIG. 9 is a schematic cross-sectional view of another embodiment of the chamber shown in FIG. 8 according to the present invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention generally provide a method and apparatus for improving the uniformity of plasma etching across the surface of a substrate, such as a photomask. Aspects of the invention will be described below in reference to an inductively coupled plasma etch chamber. Suitable inductively coupled plasma etch chambers include the Tetra™ photomask etch chamber and the Decoupled Plasma Source (DPS™) processing chamber available from Applied Materials, Inc., of Santa Clara, Calif.

Other process chambers may be used to perform the processes of the invention, including, for example, magnetically enhanced ion etch chambers as well as inductively coupled plasma etch chambers of different designs. Although the processes are advantageously performed with the Tetra™ photomask etch chamber, the description of the processing chamber is illustrative, and should not be construed or interpreted to limit the scope of any aspect of the invention. It is also contemplated that the invention may be beneficially practiced in other processing chambers, including those from other manufacturers.

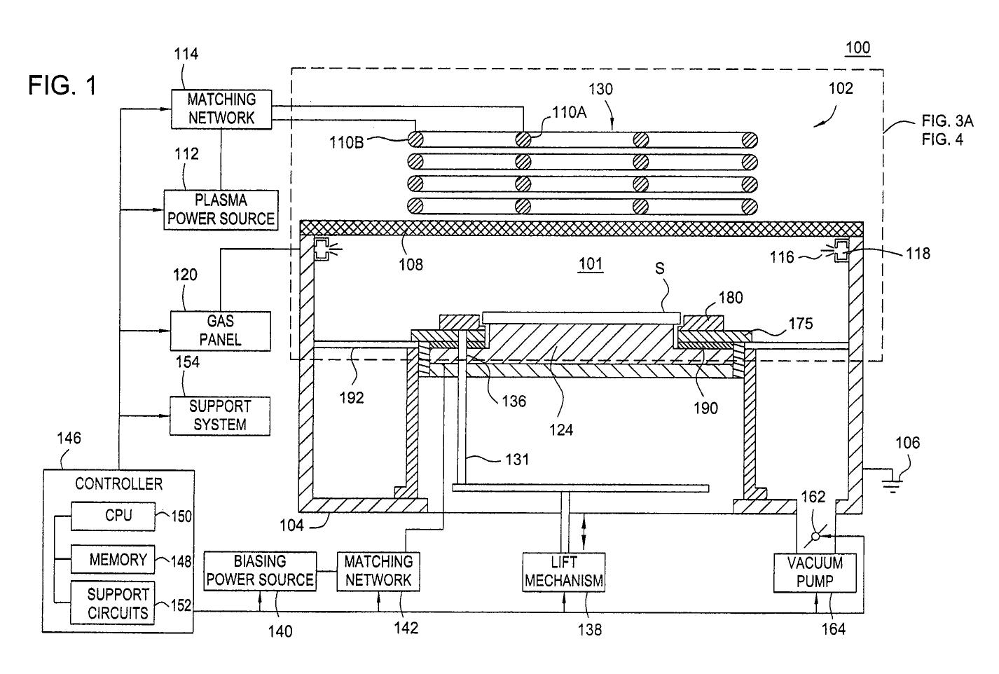

FIG. 1 is a schematic cross-sectional view of an exemplary etch reactor 100 generally comprising a processing chamber 102 having a substrate pedestal 124, processing volume 101, and a controller 146. The processing chamber 102 includes a chamber body 104 having conductive walls that support a substantially flat dielectric ceiling 108 which is transparent to radio frequency (RF) radiation. Other embodiments of the processing chamber 102 may have other types of ceilings, e.g., a dome-shaped ceiling. Induction coils 130 which are co-axially aligned and function as an antenna are disposed above the dielectric ceiling 108 and directly above the substrate pedestal 124 and processing volume 101. The induction coils 130 comprise an inner coil 110A and an outer coil 110B that are co-axial and may be selectively controlled. The induction coils 130 are coupled through a first matching network 114 to a plasma power source 112. The plasma power source 112 is typically capable of producing up to about 3000 Watts (W) at a tunable frequency in a range from about 50 kHz to about 60 MHz, with a typical operating frequency of about 13.56 MHz. The processing chamber 102 may also include a plasma screen 192 which is utilized to confine the plasma.

The substrate pedestal 124 (which acts as a cathode) supports a substrate “S” and is coupled through a second matching network 142 to a biasing power source 140. The biasing power source 140 provides between about zero to about 600 W at a tunable pulse frequency in the range of about 1 to about 10 kHz. The biasing power source 140 produces pulsed RF power output. Alternatively, the biasing power source 140 may produce pulsed DC power output. It is contemplated that the biasing power source 140 may also provide a constant DC and/or RF power output.

A gas panel 120 is coupled to the processing chamber 102 to provide process and/or other gases to the interior of the processing chamber 102. In the embodiment depicted in FIG. 1, the gas panel 120 is coupled to one or more gas inlets 116 formed in an annular gas channel 118 located within the sidewall of chamber body 104. It is contemplated that the one or more gas inlets 116 may be provided in other locations, for example, in the dielectric ceiling 108 of the processing chamber 102.

The pressure in the processing chamber 102 is controlled using a throttle valve 162 and a vacuum pump 164. The vacuum pump 164 and throttle valve 162 are capable of maintaining chamber pressures in the range of about 1 to about 30 mTorr.

The temperature of the chamber body 104 may be controlled using liquid-containing conduits (not shown) that run through the walls of the chamber body 104. Wall temperature is generally maintained at about 65 degrees Celsius. Typically, the chamber body 104 is formed from a metal (e.g., aluminum, stainless steel, and the like) and is coupled to an electrical ground 106. The etch reactor 100 also comprises conventional systems for process control, internal diagnostic, end point detection, and the like. Such systems are collectively shown as support systems 154.

The substrate pedestal 124 has a central protruding portion having a shape and dimensions that substantially match those of a typical substrate, e.g., a square shaped substrate, such as a photomask. A cover ring 175 and a capture ring 180 are disposed above the substrate pedestal 124. An annular insulator 190 is provided between an outer portion of the substrate pedestal 124 and the cover ring 175.

The capture ring 180 is designed to be moved between two positions by a lift mechanism 138 which comprises a plurality of lift pins 131 (one lift pin is shown) that travel through respective guide holes 136. In a first position, the capture ring 180 is lowered beneath the top surface of the substrate pedestal 124, leaving the substrate “S” supported by the substrate pedestal 124 for processing. In this first position, the capture ring 180 essentially couples with the protruding portions (not shown) of the cover ring 175 to form a complete annular ring such that the top surfaces of the capture ring 180 and the cover ring 175 are substantially in the same horizontal plane. At least certain portions of the capture ring 180 and the cover ring 175 are complementarily shaped, in certain embodiments. After substrate processing is completed, the capture ring 180 is lifted upwards to its second position, supporting the substrate “S” for transfer out of the processing chamber 102, and is ready for receiving another substrate for processing.

The controller 146 comprises a central processing unit (CPU) 150, a memory 148, and support circuits 152 for the CPU 150 and facilitates control of the components of the etch reactor 100 and, as such, of the etching process. The inventive method is generally stored in the memory 148 or other computer-readable medium accessible to the CPU 150 as a software routine. Alternatively, such software routine may also be stored and/or executed by a second CPU (not shown) that is remotely located from the hardware being controlled by the CPU 150.

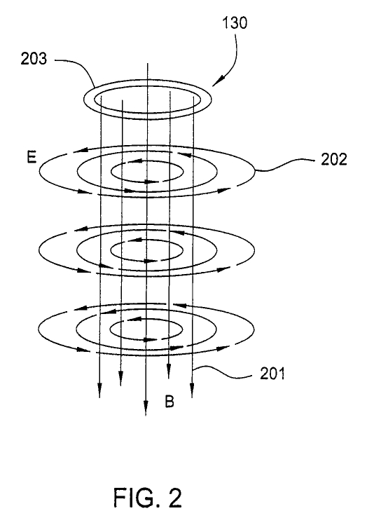

FIG. 2 is a schematic view of an electric field produced by the induction coils 130 shown in FIG. 1. A single winding 203 of the induction coil 130 is used to represent multiple windings of either the inner coil 110A or outer coil 110B. The plasma power source 112 creates a time-varying current in the windings 203 which creates a time-varying magnetic field “B” represented by magnetic field lines 201 having the direction shown (indicated by arrows) at a moment in time. The changing magnetic field produces a changing magnetic flux which creates an electric field “E” perpendicular to the magnetic field as indicated by the circular electric field lines 202. In the instant shown, the magnetic flux is increasing in magnitude and the electric field lines 202 have the direction shown (indicated by arrows, counterclockwise). As the magnetic field “B” changes, so does the magnitude and direction (clockwise or counterclockwise) of the electric field “E”. Since the processing chamber 102 has a dielectric ceiling 108 which is transparent to radio frequency (RF) radiation, the electric field “E” is inductively coupled to the processing volume 101.

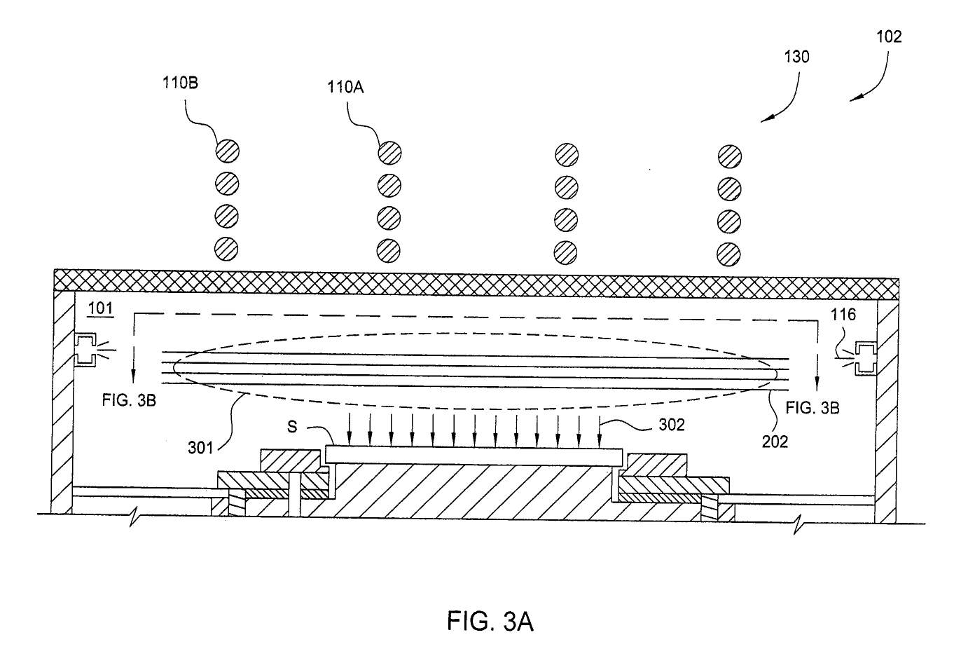

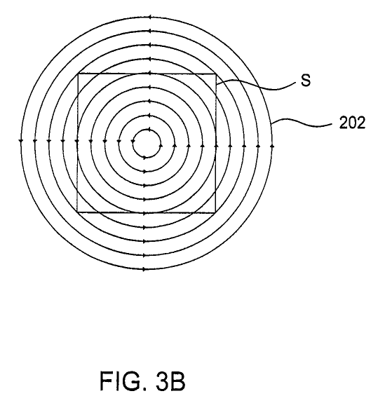

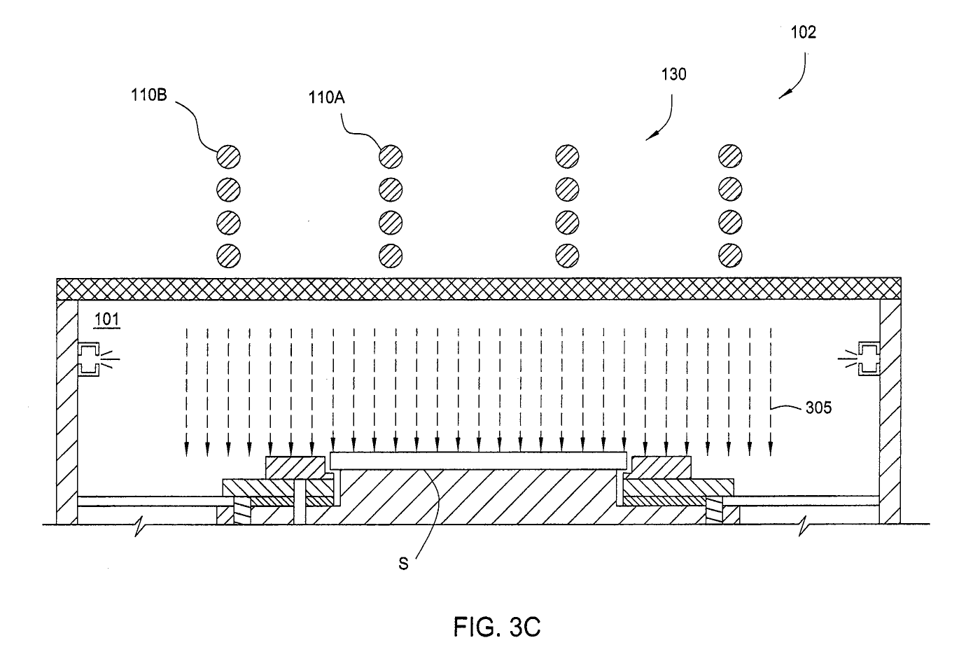

FIG. 3A is a schematic cross-sectional detail view of the chamber shown in FIG. 1. The electric field produced by the inner coil 110A and outer coil 110B is represented by an edge view of circular electric field lines 202 in processing volume 101. Process gas is provided to the processing volume 101 through gas inlets 116. The process gas may include reactive gases and inert gases (e.g., argon) to enable etching of the substrate “S.” The electric field ionizes the process gas to create a plasma 301 which is inductively coupled to the processing chamber 102 through induction coils 130. The ions created by the plasma 301 drift towards substrate “S” and are attracted to the surface of the substrate “S” by a bias electric field represented by electric field lines 302 which have the direction shown (arrows) at an instant in time (for a pulsed or alternating power source). The ions are accelerated along the direction of the bias electric field and strike the surface of the substrate “S” and etch the surface through physical (sputter etch) and/or chemical means (reactive etch). The bias electric field is provided by the biasing power source 140 which is coupled to the substrate pedestal 124.

FIG. 3B is a top view of the inductively coupled electric field shown in FIG. 3A. In one embodiment, the substrate “S” is a photomask and may have a rectangular or square shape. In another embodiment, the substrate “S” is circular in shape (e.g., semiconductor wafer). The electric field which produces plasma 301 is represented by circular electric field lines 202 which are concentric and have the direction shown (arrows) at one moment in time.

FIG. 3C shows a plasma-produced ion flux for the chamber shown in FIG. 3A. The ions produced by plasma 301 may tend to drift towards substrate “S” and then accelerate under the bias electric field as the ions near the substrate. The motion of the ions from the plasma 301 to the substrate “S” and surrounding areas defines an ion flux which is represented by ion flux lines 305 with the direction shown (arrows). The actual trajectory of any individual ion may not be parallel to the direction of the ion flux lines 305, but the net motion of many ions which move from the plasma 301 to the substrate “S” may be represented by the ion flux lines 305 as shown.

The number of ions in the ion flux may be determined in part by the number of ions produced by plasma 301, which in turn may be determined by various processing parameters, such as gas pressure and the strength of the plasma-producing electric field. The etching rate along the surface of the substrate depends in part upon the ion flux at the substrate surface, and so it may be desirable to control the number of ions and the distribution of ions at the substrate surface. For example, edge effects may cause an edge-fast etch condition along the edges of the substrate so that the substrate is etched faster along the edges than at interior regions of the substrate, and so a reduction in the number of ions striking the edges of the substrate may allow a slowing of the etch rate at the edges to provide more uniform etching across the entire substrate surface. In another example, the chamber geometry may tend to cause a center-fast etch condition at a central region of the substrate, and it may be desirable to reduce the ion flux near the center of the substrate.

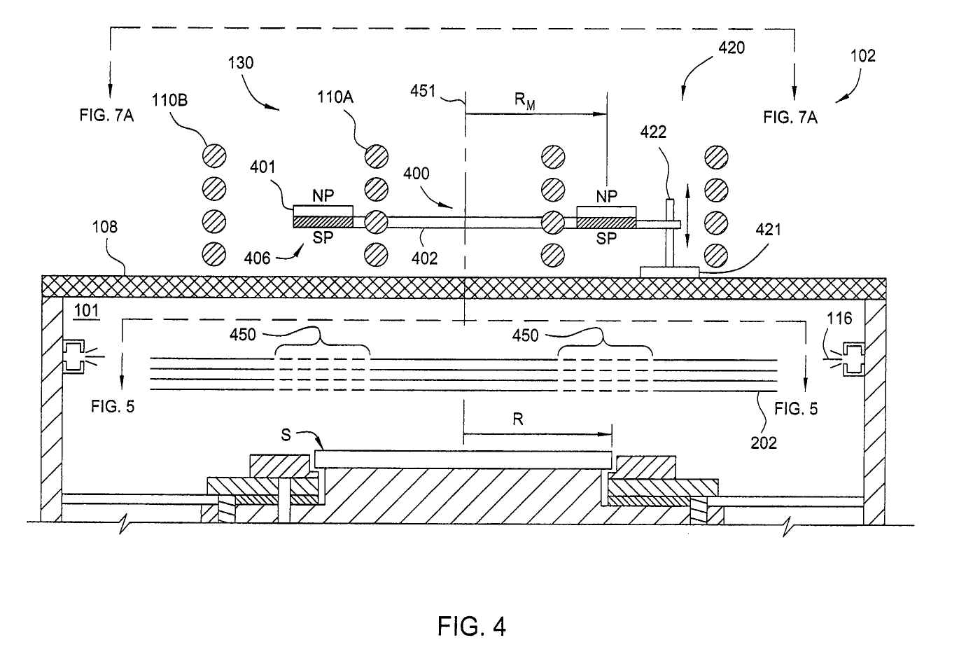

FIG. 4 is a schematic cross-sectional detail view of an etching chamber according to an embodiment of the invention that may be implemented in the etch reactor of FIG. 1. A field-shaping magnet assembly 400 is located between inner coil 110A and outer coil 110B and above dielectric ceiling 108. In another embodiment, the processing chamber 102 may have more than two induction coils 130 and the field-shaping magnet assembly 400 may be disposed within a boundary defined by one of the induction coils 130. The field-shaping magnet assembly 400 comprises a field-shaping magnet 406 and a support member 420. The field-shaping magnet 406 comprises one or more magnets 401 and a mounting base 402.

The mounting base 402 is a ring-shaped plate which encircles inner coil 110A. In another embodiment, the mounting base 402 may be a square or rectangular plate with a central opening large enough to allow the inner coil 110A to pass through, but the mounting base 402 may also have other shapes. In one embodiment, the mounting base 402 and the one or more magnets 401 are made of the same or similar materials. In another embodiment, the mounting base 402 is made of a material which is different than the material used for the one or more magnets 401.

In one embodiment, the mounting base 402 comprises a material which is transparent to the RF radiation produced by the induction coils 130 and which can withstand heating during the operation of the induction coils 130. In one example, the mounting base 402 comprises a temperatures resistant plastic, such as polyetheretherketone (e.g., PEEK), for example, although other suitable materials, other than plastics, may be used. In another embodiment, the mounting base 402 may comprise one or more magnetizable materials, which may include but are not limited to ferromagnetic materials, rare earth alloys, or alnico, for example. In yet another embodiment, the mounting base 402 may comprise a combination of magnetizable and non-magnetizable materials.

The magnet 401 comprises a ring-shaped permanent magnet coupled to the mounting base 402 and has a north pole “NP” and a south pole “SP” with the orientation shown in FIG. 4A. In another embodiment, the polarity may be reversed so that the south pole “SP” is on “top” and further from dielectric ceiling 108 and the north pole “NP” is on “bottom” and closer to the dielectric ceiling 108. In another embodiment, the magnet 401 comprises an electromagnet. The field-shaping magnet 406 may comprise one or more magnets 401, and may include a combination of permanent magnets and electromagnets. The one or more magnets 401 may comprise one or more magnetizable materials, which may include but are not limited to ferromagnetic materials, rare earth alloys, or alnico, for example.

The mounting base 402 is coupled to the support member 420 which supports the mounting base 402 and magnet 401. The support member 420 comprises a support column 422 attached to a support base 421. The support member 420 is suitably adapted so that the mounting base 402 may be moved up or down the support column 422 so that the distance of the field-shaping magnet 406 from the dielectric ceiling 108 and substrate pedestal 124 may be adjusted. In another embodiment, the distance of the field-shaping magnet 406 from the dielectric ceiling 108 is fixed. In yet another aspect of the invention, the support member 420 may be adapted to include an actuator (e.g., electric motor, air cylinder) which can raise or lower the field-shaping magnet 406 upon command from controller 146. In one embodiment, more than one support member 420 maybe used to support the field-shaping magnet 406. The support member 420 may be made of the same or similar materials as the mounting base 402 so that the support member 420 is transparent to the RF radiation produced by the induction coils 130 and can withstand heating during the operation of the induction coils 130. In another embodiment, the support member 420 comprises materials which are different from the materials used for the mounting base 402.

Referring to FIG. 4, the field-shaping magnet 406 may be aligned approximately co-axially to induction coils 130 and have a ring-shaped magnet 401 located at a distance “R_{M}” from an axis 451 of the field-shaping magnet 400. The field-shaping magnet 406 produces a static magnetic field which may interact with the changing magnetic field created by the induction coils 130. The interaction of the magnetic fields may result in a decrease in the rate of change of the magnetic flux within regions of the processing volume directly beneath the field-shaping magnet 406. According to Faraday's law, a decrease in the rate of change of the magnetic flux results in a decrease in the electric field strength for the electric field created by the changing magnetic field. This reduction in electric field strength is indicated in FIG. 4 by a depletion zone 450 shown as dashed lines for electric field lines 202. The depletion zone 450 is located approximately beneath the magnet 401 of field-shaping magnet 406 and at a radial distance “R” relative to the center of substrate “S”, and the radial distance “R” may be adjusted by adjusting the radial distance “R_{M}.” In this way, the radial profile of the plasma-producing electric field may be adjusted along the surface of substrate “S” by changing the diameter or size of the field-shaping magnet 406.

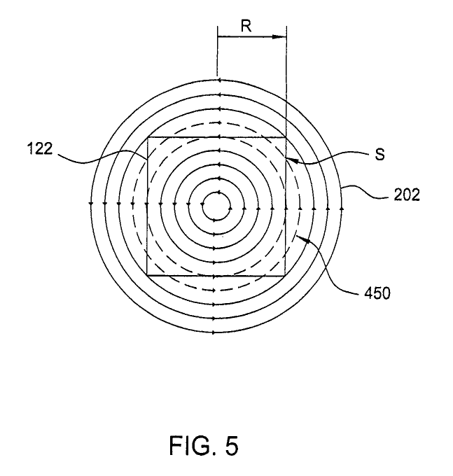

FIG. 5 is a top view of the inductively coupled electric field shown in FIG. 4. The depletion zone 450 is approximately located at radial distance “R” and near substrate edge 122. The reduced electric field strength is indicated by dashed lines for electric field lines 202. The depletion zone 450 “shadows” the ring shaped field-shaping magnet 406.

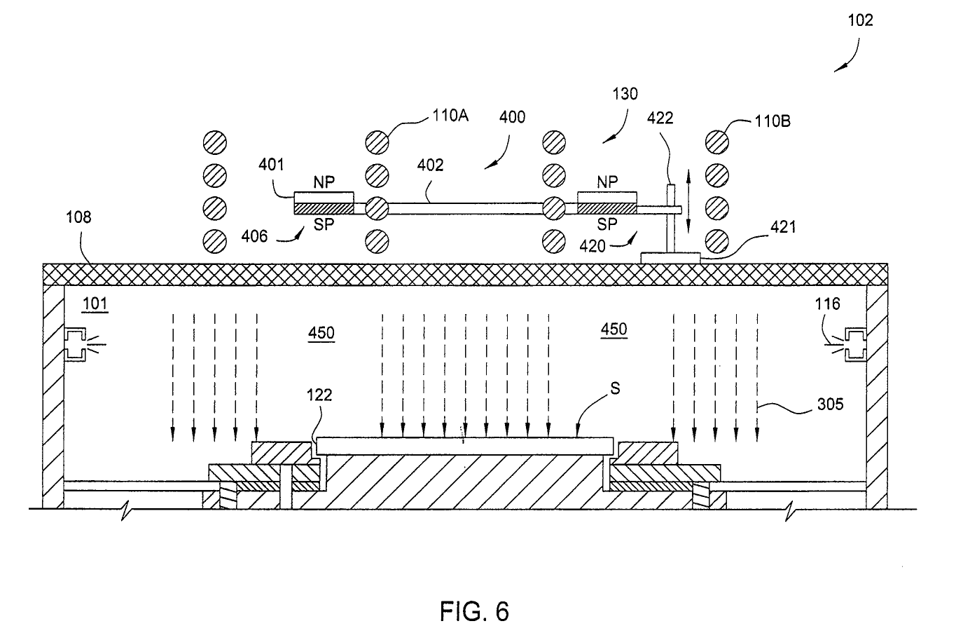

FIG. 6 shows a plasma-produced ion flux for the chamber shown in FIG. 4. The reduced electric field strength within depletion zone 450 will tend to produce a reduction in plasma density within plasma 301 with a corresponding reduction in ion flux as indicated by the absence of ion flux lines 305 in the depletion zone 450. It is to be understood that the absence of ion flux lines 305 merely indicates a reduction in the plasma density and ion flux and does not necessarily imply an absence of plasma 301 or ion flux within the depletion zone 450. The reduction in plasma density and ion flux will tend to reduce the etch rate at those regions of the substrate surface which fall within the depletion zone 450. In the example shown in FIG. 6, the depletion zone 450 is located over substrate edge 122 and so the etch rate may be reduced along the substrate edge 122. Such a reduction in etch rate at the substrate edge 122 may be desirable when an edge-fast etching condition would otherwise normally exist.

As described herein, changing the diameter or size of the field-shaping magnet 406 and, thus, the location of depletion zone 450 relative to the substrate surface provides some adjustability in the radial profile of the plasma-producing electric field. The etch rate may also be controlled along the surface of substrate “S,” for instance, by changing the diameter or size of the field-shaping magnet 406. For a given location of the depletion zone 450, the etch rate may also be controlled by moving the field-shaping magnet 406 in a vertical direction relative to the substrate “S.” For example, if the field-shaping magnet 406 is moved closer to the dielectric ceiling 108 and substrate “S”, the reduction in electric field strength and plasma density may be increased resulting in a greater reduction in etch rate within the depletion zone 450. The increased proximity of the field-shaping magnet 406 to the plasma 301 may have the effect of increasing the strength of magnet 401 relative to the induced magnetic field within processing volume 101 and thereby further reduce the strength of the plasma-producing electric field. On the other hand, if the field-shaping magnet 406 is moved further away from the dielectric ceiling 108 and substrate “S”, the effect on electric field strength and plasma density may be reduced to produce a much smaller or minimal reduction in the etch rate. As the previous examples suggest, the effect of the field-shaping magnet 406 may also be enhanced by increasing the field strength of magnets 401.

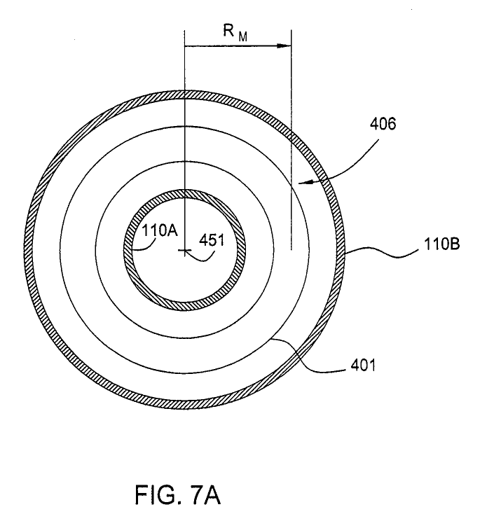

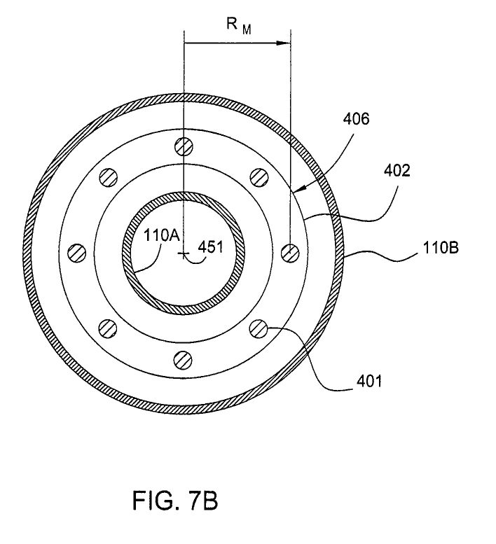

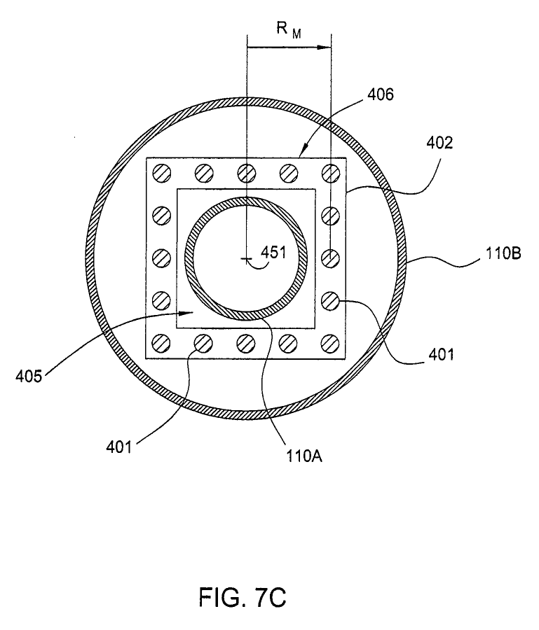

FIG. 7A is a top view of a field-shaping magnet 406 shown in FIG. 4 according to one embodiment of the invention. The field-shaping magnet 406 comprises a single, ring-shaped, permanent magnet 401 having a radius or radial distance “R_{M}” from axis 451 of the field-shaping magnet 406. The field-shaping magnet 406 is located between inner coil 110A and outer coil 110B. In another embodiment, the magnet 401 comprises an electromagnet which allows adjustability of the magnetic field strength by adjusting the current flow through the electromagnet.

FIG. 7B is a top view of a field-shaping magnet 406 shown in FIG. 4 according to a second embodiment of the invention. The field-shaping magnet 406 comprises two or more magnets 401 which are coupled to mounting base 402. The mounting base 402 is a ring-shaped plate which encircles inner coil 110A and has magnets 401 located at a radial distance “R_{M}” from axis 451 of the field-shaping magnet 406. The magnets 401 may be permanent magnets and/or electromagnets. The electromagnets may be adapted so that the current flowing through the electromagnets may be adjusted to increase or decrease the magnetic field strength simultaneously for all electromagnets. In another embodiment, the current and magnetic field strength may be separately adjusted for each electromagnet. In yet another embodiment, the current and magnetic field strength may be separately adjusted for different groups of electromagnets of the field-shaping magnet 406.

FIG. 7C is a top view of the field-shaping magnet 406 shown in FIG. 4 according to a third embodiment of the present invention. The mounting base 402 is square or rectangular in shape with a central opening or aperture 405 large enough to encircle inner coil 110A. Multiple magnets 401 are coupled to the mounting base 402. The locations of the magnets 401 may be indicated by one or more radial distances “R_{M}” which are measured from the magnet 401 to axis 451 of the field-shaping magnet 406. In another embodiment, a single, permanent magnet 401 may be coupled to mounting base 402.

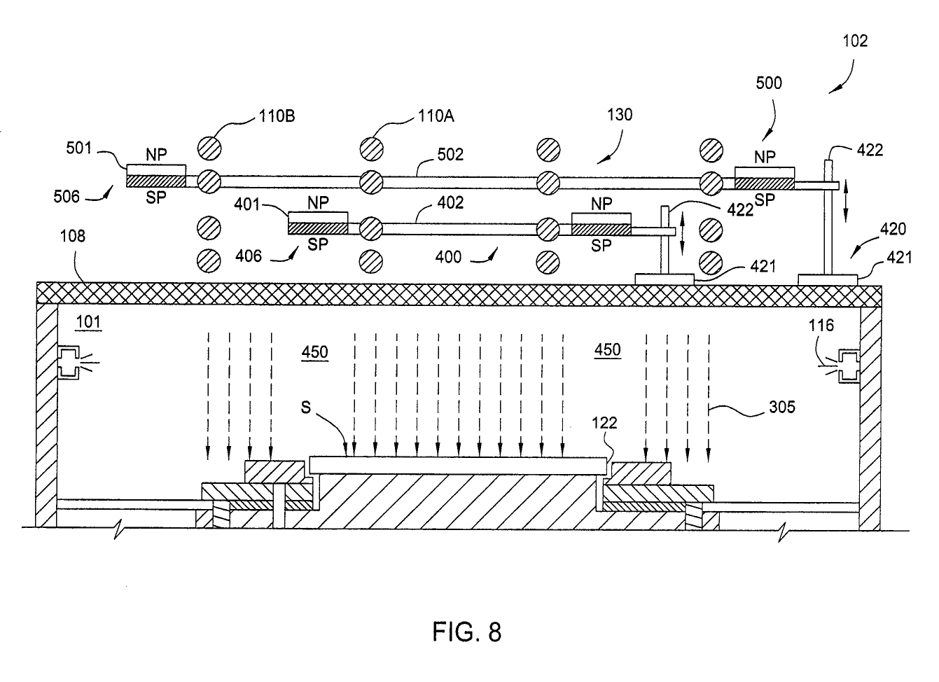

FIG. 8 is a schematic cross-sectional view of another embodiment of the chamber shown in FIG. 6 according to the present invention. A second field-shaping magnet assembly 500 is used with a first field-shaping magnet assembly 400. The field-shaping magnet assembly 500 comprises a field-shaping magnet 506 and a support member 420. The field-shaping magnet 506 comprises a magnet 501 and a mounting base 502 The magnet 501 and mounting base 502 are suitably sized to encircle outer coil 110B, and the second field-shaping magnet 506 may be used to further enhance etch rate reduction near outer areas of substrate “S”, such as areas near substrate edge 122. In another embodiment, the field-shaping magnet assembly 400 and field-shaping magnet assembly 500 are suitably adapted so that both are disposed between inner coil 110A and outer coil 110B. In a further aspect of the invention, three or more field-shaping magnets 406 and associated support members 420 may be disposed above dielectric ceiling 108 and around induction coils 130.

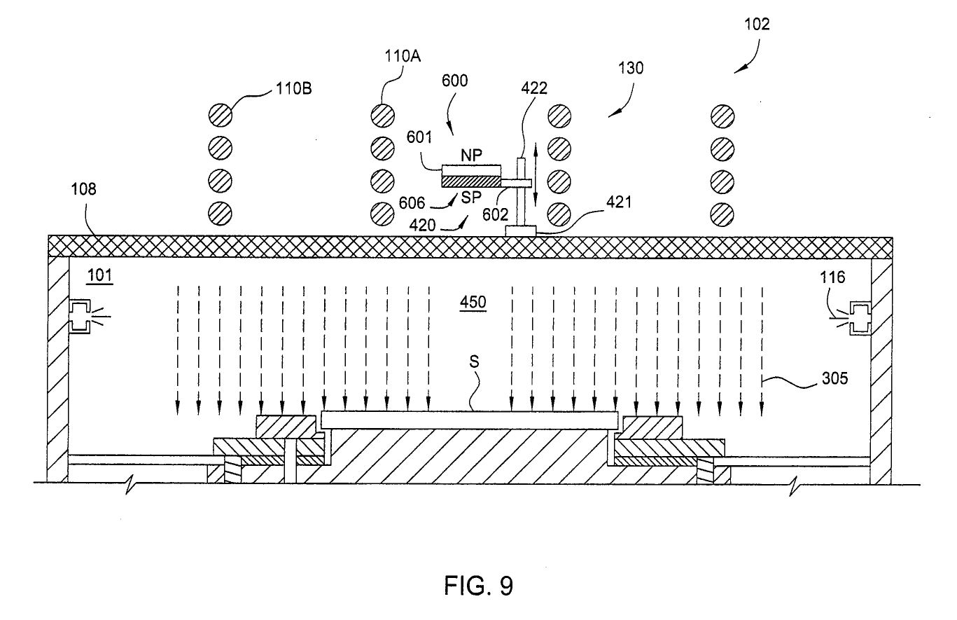

FIG. 9 is a schematic cross-sectional view of another embodiment of the chamber shown in FIG. 8 according to the present invention. A central field-shaping magnet assembly 600 is disposed within inner coil 110A. The central field-shaping magnet assembly 600 comprises a field-shaping magnet 606 and a support member 420. The field-shaping magnet 606 comprises a magnet 601 and a mounting base 602. The magnet 601 comprises a single permanent magnet located above a central area of the substrate “S.” In another aspect of the invention, the magnet 601 comprises a single electromagnet. In another embodiment, the field-shaping magnet 606 is adapted to include multiple magnets 601 which may be disposed on mounting base 602 as shown in FIGS. 7B and 7C. The field-shaping magnet 606 produces a depletion zone 450 located over a central area of substrate “S” and may be useful in reducing the etch rate near the substrate center. The embodiments shown in FIGS. 4, 7A-7C, 8 and 9 and described herein may be combined and used with other embodiments described herein for the field-shaping magnet assembly 400.

While the foregoing is directed to embodiments of the present invention, other and further embodiments of the invention may be devised without departing from the basic scope thereof, and the scope thereof is determined by the claims that follow.

1. An apparatus for plasma etching, comprising:
a process chamber defining a processing volume;
a substrate pedestal disposed in the process chamber and configured to support a substrate thereon;
one or more induction coils disposed outside the chamber above the substrate pedestal; and
a field-shaping magnet assembly having a field-shaping magnet, said assembly disposed adjacent to an induction coil.

2. The apparatus of claim 1, wherein the induction coils comprise an inner coil and an outer coil.

3. The apparatus of claim 1, wherein the field-shaping magnet assembly is disposed within a boundary defined by one of the induction coils.

4. The apparatus of claim 1, wherein the field-shaping magnet assembly comprises one or more permanent magnets.

5. The apparatus of claim 1, wherein the field-shaping magnet assembly comprises one or more electromagnets.

6. The apparatus of claim 2, wherein the field-shaping magnet encircles the inner coil but not the outer coil.

7. The apparatus of claim 6, further comprising a second field-shaping magnet assembly disposed outside the outer coil wherein the field-shaping magnet encircles the outer coil.

8. The apparatus of claim 1, wherein the vertical distance of the field-shaping magnet from the substrate pedestal can be adjusted.

9. The apparatus of claim 2, wherein the field-shaping magnet is located centrally within the inner coil.

10. The apparatus of claim 1, wherein the substrate pedestal is adapted to support a photomask.

11. The apparatus of claim 5, wherein the current supplied to the electromagnets can be adjusted.

12. The apparatus of claim 1, wherein the field-shaping magnet assembly comprises a combination of permanent magnets and electromagnets.

13. A method of etching a substrate using a processing chamber having a substrate pedestal and induction coils disposed outside the chamber and above the substrate pedestal, and at least one field-shaping magnet disposed adjacent to an induction coil and above said pedestal, the method comprising:
generating an electric field within a substrate processing volume using the induction coils; and
selectively modifying the electric field using the at least one field-shaping magnet.

14. The method of claim 13, wherein the substrate is a photomask.

15. The method of claim 13, wherein selectively modifying the electric field comprises adjusting the vertical distance of the field-shaping magnet from the substrate pedestal.

16. The method of claim 13, further comprising:
providing a second field-shaping magnet adjacent to an induction coil and above the substrate pedestal; and
positioning the second field-shaping magnet to selectively modify the electric field.

17. An apparatus for plasma etching, comprising:
a process chamber defining a processing volume;
a substrate pedestal disposed in the process chamber and configured to support a substrate thereon;
one or more induction coils disposed outside the chamber and above the substrate pedestal; and
a field-shaping magnet assembly disposed within a boundary defined by one of the induction coils, the field-shaping magnet assembly comprising:
a field-shaping magnet having a magnet and mounting base; and
a support member having a support column and support base.

18. The apparatus of claim 17, wherein the field-shaping magnet comprises multiple magnets.

19. The apparatus of claim 17, wherein the mounting base is a ring-shaped plate.

20. The apparatus of claim 17, wherein the support member is adapted so that the vertical distance of the field-shaping magnet from the substrate pedestal can be adjusted.

21. The apparatus of claim 20, wherein the support member further comprises an actuator which is adapted to raise and lower the field-shaping magnet upon command from a controller.

22. The apparatus of claim 17, wherein the induction coils comprise an inner coil and an outer coil.

23. A processing chamber component used to modify an electric field produced inside the chamber by induction coils disposed outside the chamber, the component comprising:
a field-shaping magnet assembly disposed within a boundary defined by one of the induction coils, the field-shaping magnet assembly comprising:
a field-shaping magnet having a magnet and mounting base; and
a support member having a support column and support base;
wherein the field-shaping magnet can modify the strength of the electric field in a radial direction parallel to a substrate support.
